(19) United States
(12) Patent Application Publication
(10) Pub. No.: US 2022/0379412 A1
(43) Pub. Date: Dec. 1, 2022

(54) AL2O3-BASED CERAMIC WELDING SEALING COMPONENT AND PREPARATION METHOD THEREOF

(71) Applicant: Hunan Nhy Technology Limited, Loudi (CN)

(72) Inventors: Jianping CAO, Loudi (CN); Jianhui CAO, Loudi (CN); Ping LIU, Loudi (CN)

(73) Assignee: Hunan Nhy Technology Limited, Loudi (CN)

(21) Appl. No.: 17/580,887

(22) Filed: Jan. 21, 2022

(30) Foreign Application Priority Data
Jun. 1, 2021 (CN) 2021106072179

(51) Int. Cl. B23K 35/365

(52) U.S. Cl. CPC B23K 35/365; B23K 2103/52

(57) ABSTRACT

The present invention discloses an Al₂O₃-based ceramic welding sealing component and a preparation method thereof, and relates to the technical field of metalized ceramic processing. The Al₂O₃-based ceramic welding sealing component disclosed in the present invention comprises a ceramic matrix and a metallized layer. The ceramic matrix is made from raw materials such as an inorganic fiber-aluminum oxide 3D network matrix, yttrium oxide, silicon oxide, titanium oxide, an additive, a binder and a dispersant, through steps such as preparation of the inorganic fiber-aluminum oxide 3D network matrix, mixing, pelletizing, primary sintering and secondary sintering; and the raw materials of the metallized layer comprise titanium powder, tungsten powder, molybdenum oxide, boron oxide, yttrium oxide and an organic binder. Al₂O₃-based ceramic welding sealing component provided by the present invention has high efficiency of space filling and tensile strength, excellent tensile strength, toughness and high-temperature resistance.

### CROSS-REFERENCE TO RELATED APPLICATIONS

The application claims priority to Chinese patent application No.2021106072179, filed on Jun. 1, 2021, the entire contents of which are incorporated herein by reference.

### TECHNICAL FIELD

The present invention belongs to the technical field of metalized ceramic processing, and particularly relates to an Al₂O₃-based ceramic welding sealing component and a preparation method thereof.

### BACKGROUND

With the development of material technology, ceramic materials have been widely used. Especially in sealing mechanisms, ceramic materials are suitable for various sealing components due to their high-temperature resistance, chemical corrosion resistance and thermal conductivity. At present, the ceramic welding sealing component is composed of metalized ceramic. The ceramic materials used in the metallization process mainly include alumina, zirconia, silicon nitride, silicon carbide, tungsten carbide and composite thereof. Among them, silicon carbide ceramics are most widely used because of their excellent strength, hardness and chemical corrosion resistance. The cost performance is much higher than that of ordinary metal seals, and the service life is greatly prolonged. However, silicon nitride ceramics have low fracture toughness, i. e. high brittleness, easy fracture, and poor sealing strength with metal layers.

Aluminum oxide ceramic has the characteristics of high mechanical strength, good wear resistance and corrosion resistance, good thermal stability, large insulation resistance, and matchable expansion coefficient with the chip, and is the most common matrix material or packaging shell material in the field of microelectronic packaging. In order to provide high strength and high hermeticity to electronic devices or package shells, Al₂O₃ ceramics often need to be brazed with packaging metals such as various alloys. However, the common metal solder has poor wettability with the Al₂O₃ ceramic, so it is necessary to perform metallization on the surface of the Al₂O₃ ceramic. One of the most common methods is to co-burn a tungsten metallized layer on the surface, and then perform electroplating Ni or Au on the Al₂O₃ ceramic having the tungsten metallized layer, so that the Al₂O₃ ceramic and alloy can be brazed using a conventional solder such as Ag—Cu, thereby obtaining a gastight package. The traditional tungsten metallizing layer of aluminum oxide ceramic is mainly composed of tungsten powder and glass powder. This metallized layer has the disadvantages of low efficiency of space filling and high porosity, which affects the mechanical properties and service life of the ceramic metallized product. Aluminum oxide ceramics have the defects of high brittleness, low impact resistance and brittleness, which also affect the use of aluminum oxide in sealing components and reduce the service life of aluminum oxide ceramics.

### SUMMARY

The present invention provides a metallized aluminum oxide ceramic and a preparation method thereof for use on an Al₂O₃-based ceramic welding sealing component. The main purpose is to improve the efficiency of space filling of the sealing components, greatly improve the bending strength and fracture toughness of the sealing components, increase the tensile strength of the sealing components, and have excellent high-temperature resistance.

In order to achieve the object of the present invention, the present invention provides an Al₂O₃-based ceramic welding sealing component comprising a ceramic matrix and a metallized layer, wherein the ceramic matrix is prepared from the following raw materials in parts by weight: 80-90 parts of inorganic fiber-aluminum oxide 3D network matrix, 2-5 parts of yttrium oxide, 1-3 parts of silicon oxide, 2-4 parts of titanium oxide, 0.5-1.0 parts of additive, 3-5 parts of binder and 1-3 parts of dispersant, and the additive, binder and dispersant are LiYO₂, polyvinyl butyral and sodium tripolyphosphate respectively;

a preparation method of the ceramic matrix comprising the steps of:

A1, preparation of inorganic fiber-hexagonal aluminum oxide 3D network matrix:

impregnating the inorganic fibers in a 2 mol/L NaOH solution and a silicone insulating impregnating agent, impregnating for 3-4 h at 70-90° C., filtering and drying to obtain surface-modified inorganic fibers, wherein the mass ratio of the NaOH solution and the silicone insulating impregnating agent is 1:1-2;

mixing the aluminum oxide and the surface-modified inorganic fibers, and reacting under an inert atmosphere at a pressure of 5-10 MPa and a temperature of 80-120° C. for 2-6 h to prepare the inorganic fiber-hexagonal aluminum oxide 3D network matrix, wherein the mass ratio of the surface-modified inorganic fibers to aluminum oxide is 1:4-8;

A2, mixing: mixing silicon oxide, yttrium oxide and the additive uniformly, adding same to the inorganic fiber-aluminum oxide 3D network matrix prepared in step A1, then adding titanium oxide, the dispersant and water, and performing high-speed ball-milling for 6-8 h;

A3, granulation: performing suction filter on the milled slurry, and then processing same into a granular ceramic powder with an average particle size of 20-40 μm by a centrifugal spray drier for later use;

A4, primary sintering: loading the ceramic powder obtained in step A3 into a hot-pressing mold, and performing normal temperature sintering at 1000-1200° C. with nitrogen as a protective gas, with the temperature-holding time being 1-2 h to prepare a ceramic blank; and

A5, secondary sintering: loading the ceramic blank obtained in step A4 into a hot-pressing mold, using nitrogen as a protective gas, sintering at 1600-1800° C. under normal pressure, with the temperature-holding time being 2-3 h; after cooling to room temperature in a furnace, taking out the sintered product, and then polishing same on a surface grinding machine to prepare a ceramic matrix to be metallized.

Further, the inorganic fiber of step A1 is one of silicon carbide fiber, aluminum nitride fiber or silicon oxide fiber.

Further, in the ball-milling process of step A2, the ball-milling rate is 360 r/min, and the ball material ratio is 10:1.

A preparation method of an Al₂O₃-based ceramic welding sealing component, comprising the steps of:

B 1, preparation of metallized paste: weighing 10-20 parts of titanium powder, 40-60 parts of tungsten powder, 10-20 parts of molybdenum oxide, 10-20 parts of boron oxide, 2-4 parts of yttrium oxide and 2-5 parts of an organic binder, uniformly mixing the titanium powder, tungsten powder, molybdenum oxide, boron oxide, yttrium oxide and the organic binder together to prepare a metallized paste;

B2, silk-screen: ultrasonically cleaning the surface of the ceramic matrix to be metallized prepared in claim 1 with anhydrous ethanol, and then uniformly coating the metallized paste on the surfaces of both ends of the ceramic matrix by means of silk-screen printing, wherein the printing thickness of the metallized paste is 40-50 μm; and

B3, metallization: sintering the ceramic matrix coated with the metallized paste prepared above under vacuum or inert gas protection, with the sintering temperature being 1300-1500° C., and the sintering temperature-holding time being 60-90 min, so as to obtain the Al₂O₃-based ceramic welding sealing component of the present invention.

Further, the organic binder in step B1 is made by mixing according to a weight ratio of ethyl cellulose: terpineol: ethylene glycol=2:1:1.

Compared with the prior art, the present invention has the beneficial effects that:

1. The sodium tripolyphosphate of the present invention is an anionic hydrophilic surfactant. In water, the sodium tripolyphosphate is ionized to form anions, and is adsorbed on the surface of oxides (yttrium oxide, silicon oxide and titanium oxide), so that an electric double layer is formed at the interface between the oxide molecules and water, and the oxides are negatively charged due to the adsorption of anions on the surface. The oxides with the same charge are repelled by the electrostatic repulsion, which prevents the particles from aggregating with each other, thereby improving the dispersion effect of the oxides.

2. In the present invention, SiO₂—Y₂O₃ as a sintering aid forms a liquid phase during high-pressure and high-temperature sintering under the action of an additive, and the mass transfer and condensation of the grains of the inorganic fiber-hexagonal aluminum oxide 3D network matrix in the liquid phase are fast, facilitating the diffusion and migration of grain boundaries, so that the SiO₂—Y₂O₃ as the sintering aid can significantly improve the efficiency of space filling and mechanical properties of the ceramic matrix.

3. The titanium powder in the metallized paste of the present invention has a strong chemical activity and a great affinity for molybdenum oxide, boron oxide and yttrium oxide. At the sintering temperature, the titanium powder and molybdenum oxide, boron oxide and yttrium oxide form a liquid phase active alloy to penetrate to the surface of the ceramic matrix to form a very compact and uniform metal layer, so that the ceramic matrix and the metal layer are sealed with high strength and high air tightness, which greatly improves the wettability of the ceramic matrix.

4. The titanium oxide in the ceramic matrix of the present invention can interact with the oxide in the metallized paste, so that the viscosity of the glass phase in the ceramic matrix is reduced and the surface of the titanium particles in the metallized layer is well wetted. At the same time, the glass phase in the ceramic matrix is promoted to migrate to the metallized layer by capillary action penetrating into the gaps of the titanium particles in the metallized layer, thereby improving the wettability of the ceramic matrix.

5. In the present invention, a 3D network structure is prepared by using an inorganic fiber as a reinforcing agent through cross-linking the aluminum oxide and the surface-modified inorganic fiber at high-temperature and high pressure. The 3D network structure is beneficial to the compactness of the ceramic matrix, greatly improving the temperature resistance and mechanical properties of the ceramic matrix. The oxide is filled in the inorganic fiber-aluminum oxide 3D network matrix under the action of the dispersant and is ground, and the inorganic fiber component is used as a ball-milling medium to reduce the particle size of the inorganic fiber-aluminum oxide 3D network matrix and improve the efficiency of space filling and mechanical properties of the ceramic matrix. A compact ceramic matrix is formed under the action of a binder, and the inorganic fiber-aluminum oxide 3D network structure can disperse and eliminate various stresses generated in the interior of the ceramic and introduced by aluminum oxide, so that the ceramic matrix has good flexibility, and improved bending strength.

6. In the sintering process of the metallized layer, titanium powder and molybdenum oxide, boron oxide and yttrium oxide form a glass phase, and the glass phase migrates into tungsten powder particles, so that the position of the tungsten powder is adjusted, achieving a tight arrangement again, resulting in a high efficiency of space filling of the metallized layer. At the same time, the atoms on the surface of the tungsten powder will be dissolved in the glass phase, and since the glass phase in the metallized layer and the liquid phase in the ceramic matrix are mutually soluble, the liquid phase in the ceramic matrix will be promoted to migrate into the pores of the tungsten powder, and at the same time, the glass phase in the metallized layer and the tungsten powder dissolved in the glass phase penetrate into the ceramic matrix. The 3D network structure of the ceramic matrix can make the glass phase of the metallized layer more easily migrate into the 3D network structure of the ceramic matrix, strengthening the connection between the ceramic matrix and the metallized layer, and enhancing the wettability of the ceramic matrix. Yttrium oxide in the composition of the metallized layer reacts readily with aluminum oxide in the ceramic matrix at high-temperatures to produce liquid phase YAP, further improving the wetting of the metallized layer by the ceramic matrix.

7. In the present invention, by using 3D network matrix of inorganic fibers and aluminum oxide, and using yttrium oxide-silicon oxide-titanium oxide as a sintering aid to obtain a ceramic matrix with a high efficiency of space filling, which has excellent bending properties, fracture toughness, insulation properties and high-temperature resistance. The sealing component prepared by metallizing the ceramic matrix of the present invention using titanium powder, tungsten powder and the like as the metallized paste has a very good efficiency of space filling, and has a high tensile strength and excellent high-temperature resistance because the metallized paste has a very good sealing effect with the ceramic matrix of the present invention.

### DETAILED DESCRIPTION OF THE EMBODIMENTS

The technical solutions in the embodiments of the present invention will be described clearly and completely. Obviously, the described embodiments are only a part of the embodiments of the present invention, rather than all the embodiments. Based on the embodiments of the present invention, all other embodiments obtained by a person of ordinary skill in the art without inventive effort fall within the scope of the present invention.

Hereinafter, the Al₂O₃-based ceramic welding sealing component and preparation method thereof according to the present invention will be described with reference to specific examples.

Example 1: Al₂O₃-based ceramic welding sealing component comprising a ceramic matrix and a metallized layer, the ceramic matrix and a preparation method thereof

The ceramic matrix in the sealing component comprise the following raw materials in parts by weight: 80 parts of an inorganic fiber-aluminum oxide 3D network matrix, 5 parts of yttrium oxide, 3 parts of silicon oxide, 4 parts of titanium oxide, 21 parts of LiYO2, 4.5 parts of polyvinyl butyral and 3 parts of sodium tripolyphosphate;

The preparation method of the ceramic matrix according to the above formula components comprises the following steps:

A1. preparation of a silicon carbide fiber-aluminum oxide 3D network matrix:

The silicon carbide fiber was impregnated in a 2 mol/L NaOH solution and a silicone insulating impregnating agent for 3-4 h at 70-90° C.; through filtering and drying, a surface-modified silicon carbide fibers were obtained, wherein the mass ratio of the NaOH solution and the silicone insulating impregnating agent was 1:1; and

the aluminum oxide and the surface-modified silicon carbide fibers were mixed, and reacted under an inert atmosphere at a pressure of 5-10 MPa and a temperature of 80-120° C. for 2-6 h to prepare a silicon carbide fiber-aluminum oxide 3D network matrix, wherein the mass ratio of the surface-modified silicon carbide fiber to aluminum oxide was 1:4;

A2, mixing: silicon oxide, yttrium oxide and an additive were mixed uniformly, and added to the silicon carbide fiber-aluminum oxide 3D network matrix prepared in step A1; and then titanium oxide, the dispersant and water were added, and ball-milling was performed at a rate of 360 r/min for 6-8 h, wherein the ball-to-material ratio was 10:1;

A3, granulation: the milled slurry was subjected to suction filter, and was then processed into a granular ceramic powder with an average particle size of 20-40 μm by a centrifugal spray drier for later use;

A4, primary sintering: the ceramic obtained in step A3 was loaded into a hot-pressing mold, and subjected to normal temperature sintering at 1000-1200° C. with nitrogen as a protective gas, with the temperature-holding time being 1-2 h, to obtain a ceramic blank; and

A5, secondary sintering: the ceramic blank obtained in step A4 was loaded into the hot-pressing mold, and sintered at 1600-1800° C. under normal pressure using nitrogen as a protective gas, with the temperature-holding time being 2-3 h; the sintered product was cooled to room temperature in a furnace, taken out, and polished on a surface grinding machine to obtain a ceramic matrix to be metallized.

Example 2: Al₂O₃-based ceramic welding sealing component comprising a ceramic matrix and a metallized layer, the ceramic matrix and a preparation method thereof

The ceramic matrix in the sealing component comprise the following raw materials in parts by weight: 85 parts of an inorganic fiber-aluminum oxide 3D network matrix, 3 parts of yttrium oxide, 2 parts of silicon oxide, 3 parts of titanium oxide, 0.8 parts of LiYO₂, 5 parts of polyvinyl butyral and 1.2 parts of sodium tripolyphosphate.

The preparation method of the ceramic matrix in example 2 was the same as that in example 1, and the specific steps were referred to example 1. It is noted that in step A1, the inorganic fibers were aluminum nitride fibers, the mass ratio of NaOH solution to the silicone insulation impregnant was 1:2, and the mass ratio of the surface-modified silicon carbide fibers to the aluminum oxide was 1:6.

Example 3: Al₂O₃-based ceramic welding sealing component comprising a ceramic matrix and a metallized layer, the ceramic matrix and a preparation method thereof

The ceramic matrix in the sealing component comprise the following raw materials in parts by weight: 90 parts of an inorganic fiber-aluminum oxide 3D network matrix, 2 parts of yttrium oxide, 1 parts of silicon oxide, 2 parts of titanium oxide, 1 parts of LiYO₂, 3 parts of polyvinyl butyral and 1 parts of sodium tripolyphosphate.

The preparation method of the ceramic matrix in example 3 was the same as that in example 1, and the specific steps were referred to example 1. It is noted that in step A1, the inorganic fibers were silicon oxide fibers, the mass ratio of NaOH solution to the silicone insulation impregnant was 1:1.5, and the mass ratio of the surface-modified silicon carbide fibers to the aluminum oxide was 1:8.

Example 4: Al₂O₃-based ceramic welding sealing component comprising a ceramic matrix and a metallized layer, the ceramic matrix and a preparation method thereof

The ceramic matrix in the sealing component comprise the following raw materials in parts by weight: 82 parts of an inorganic fiber-aluminum oxide 3D network matrix, 4.5 parts of yttrium oxide, 3 parts of silicon oxide, 2.8 parts of titanium oxide, 0.7 parts of LiYO₂, 5 parts of polyvinyl butyral and 2 parts of sodium tripolyphosphate.

The preparation method of the ceramic matrix in example 4 was the same as that in example 1, and the specific steps were referred to example 1. It is noted that in step A1, the inorganic fibers were silicon carbide fibers, the mass ratio of NaOH solution to the silicone insulation impregnant was 1:2, and the mass ratio of the surface-modified silicon carbide fibers to the aluminum oxide was 1:5.5.

Example 5: composition of metallized layer in Al₂O₃-based ceramic welding sealing component and preparation method of sealing component

The metallized paste comprises the following raw materials in parts by weight: 10 parts of titanium powder, 60 parts of tungsten powder, 10 parts of molybdenum oxide, 13 parts of boron oxide, 2 parts of yttrium oxide and 5 parts of an organic binder, wherein the organic binder is mixed by ethyl cellulose: terpineol: ethylene glycol in a weight ratio of 2:1:1.

A preparation method of an Al₂O₃-based ceramic welding sealing component comprising the steps of:

B1, preparation of metallized paste: the above-mentioned parts of titanium powder, tungsten powder, molybdenum oxide, boron oxide, yttrium oxide and the organic binder were uniformly mixed together to prepare a metallized paste;

B2, silk-screen: the surface of the ceramic matrix to be metallized prepared in example 1 was ultrasonically cleaned with anhydrous ethanol; and then the metallized paste was uniformly coated on the surfaces of both ends of the ceramic matrix by means of silk-screen printing, wherein the printing thickness of the metallized paste is 40-50 μm; and

B3, metallization: the ceramic matrix coated with the metallized paste prepared above was sintered under vacuum or inert gas protection, with the sintering temperature being 1300-1500° C., and the sintering temperature-holding time being 60-90 min, so as to obtain the Al₂O₃-based ceramic welding sealing component of the present invention C1.

Example 6: composition of metallized layer in Al₂O₃-based ceramic welding sealing component and preparation method of sealing component

The metallized paste comprises the following raw materials in parts by weight:

15 parts of titanium powder, 55 parts of tungsten powder, 13 parts of molybdenum oxide, 10 parts of boron oxide, 3 parts of yttrium oxide and 4 parts of an organic binder, wherein the organic binder is mixed by ethyl cellulose: terpineol: ethylene glycol in a weight ratio of 2:1:1.

A preparation method of an Al₂O₃-based ceramic welding sealing component comprising the steps of:

B1, preparation of metallized paste: the above-mentioned parts of titanium powder, tungsten powder, molybdenum oxide, boron oxide, yttrium oxide and the organic binder were uniformly mixed together to prepare a metallized paste;

B2, silk-screen: the surface of the ceramic matrix to be metallized prepared in example 2 was ultrasonically cleaned with anhydrous ethanol; and then the metallized paste was uniformly coated on the surfaces of both ends of the ceramic matrix by means of silk-screen printing, wherein the printing thickness of the metallized paste was 40-50 μm; and

B3, metallization: the ceramic matrix coated with the metallized paste prepared above was sintered under vacuum or inert gas protection, with the sintering temperature being 1300-1500° C., and the sintering temperature-holding time being 60-90 min, so as to obtain the Al₂O₃-based ceramic welding sealing component of the present invention C2.

Example 7: composition of metallized layer in Al₂O₃-based ceramic welding sealing component and preparation method of sealing component

The metallized paste comprises the following raw materials in parts by weight: 18 parts of titanium powder, 50 parts of tungsten powder, 10 parts of molybdenum oxide, 15 parts of boron oxide, 4 parts of yttrium oxide and 3 parts of an organic binder, wherein the organic binder is mixed by ethyl cellulose: terpineol: ethylene glycol in a weight ratio of 2:1:1.

A preparation method of an Al₂O₃-based ceramic welding sealing component comprising the steps of:

B1, preparation of metallized paste: the above-mentioned parts of titanium powder, tungsten powder, molybdenum oxide, boron oxide, yttrium oxide and the organic binder were uniformly mixed together to prepare a metallized paste;

B2, silk-screen: the surface of the ceramic matrix to be metallized prepared in example 3 was ultrasonically cleaned with anhydrous ethanol; and then the metallized paste was uniformly coated on the surfaces of both ends of the ceramic matrix by means of silk-screen printing, wherein the printing thickness of the metallized paste was 40-50 μm; and

B3, metallization: the ceramic matrix coated with the metallized paste prepared above was sintered under vacuum or inert gas protection, with the sintering temperature being 1300-1500° C., and the sintering temperature-holding time being 60-90 min, so as to obtain the Al₂O₃-based ceramic welding sealing component of the present invention C3.

Example 8: composition of metallized layer in Al₂O₃-based ceramic welding sealing component and preparation method of sealing component

The metallized paste comprises the following raw materials in parts by weight: 20 parts of titanium powder, 40 parts of tungsten powder, 20 parts of molybdenum oxide, 15 parts of boron oxide, 3 parts of yttrium oxide and 2 parts of an organic binder, wherein the organic binder is mixed by ethyl cellulose: terpineol: ethylene glycol in a weight ratio of 2:1:1.

A preparation method of an Al₂O₃-based ceramic welding sealing component comprising the steps of:

B1, preparation of metallized paste: the above-mentioned parts of titanium powder, tungsten powder, molybdenum oxide, boron oxide, yttrium oxide and the organic binder were uniformly mixed together to prepare a metallized paste;

B2, silk-screen: the surface of the ceramic matrix to be metallized prepared in example 4 was ultrasonically cleaned with anhydrous ethanol; and then the metallized paste was uniformly coated on the surfaces of both ends of the ceramic matrix by means of silk-screen printing, wherein the printing thickness of the metallized paste was 40-50 μm; and

B3, metallization: the ceramic matrix coated with the metallized paste prepared above was sintered under vacuum or inert gas protection, with the sintering temperature being 1300-1500° C., and the sintering temperature-holding time being 60-90 min, so as to obtain the Al₂O₃-based ceramic welding sealing component of the present invention C4.

The tensile strength of the Al₂O₃-based ceramic welding sealing components prepared in Examples 5-8 was tested as follows:

The tensile strength was tested by three-point method. Namely, three points were uniformly selected at one end face of the seal component, and on each point, placed was a 0.1 mm thick silver copper solder piece of Φ3 mm. Then three ψ3 mm×30 mm iron-nickel-cobalt porcelain seal alloy rods were vertically and smoothly pressed on the solder piece with clamps, respectively, and placed in a vacuum brazing furnace for brazing. Finally, the sealed test piece was subjected to a tension test on a material testing machine. The tensile strength value was calculated according to the equation E=10P/F, wherein: E-tensile strength (MPa), P-force at break (KN), and F-sealing area of test piece cm². The test equipment was a CSS-44100 universal material testing machine.

Compared with the preparation method of a high-alumina ceramic disclosed in invention patent CN109336564B and the high-alumina ceramic prepared by the method, the comparative test results of the tensile strength of the Al₂O₃-based ceramic welding sealing components obtained in the above-mentioned embodiments 5-8 are shown in Table 1.

TABLE 1
Test results of tensile strength of seal components

| | C1 | C2 | C3 | C4 | Comparative |
|---|---|---|---|---|---|
| Flexural | 204 | 216 | 210 | 208 | 162 |
| Strength, MPa | | | | | |

The ceramic matrixes of Examples 1-4 were tested for efficiency of space filling, flexural strength, and fracture toughness.

(1) Test method for efficiency of space filling of ceramic matrix:

Test for Bulk Density

1) The sample to be tested was placed in an oven at 100±5° C. to dry to a constant weight, and the dry weight mi of the sample to be tested was weighed by an analytical balance at room temperature, with the accuracy of 0.001 g;

2) the sample to be tested weighed in step 1) was placed into boiling water for boiling for not less than 3 h; the sample was kept below the liquid level during boiling; after cooling to room temperature, the floating weight in water m₂ of the sample to be tested was weighed by the analytical balance, with the accuracy of 0.001g; and

3) The sample to be tested weighed in step 2) was taken out of water, and the water on the surface of sample was wiped with a gauze; and then the wet weight m3 of the sample was quickly weighed, with the accuracy of 0.001g.

4) The above steps were repeated for 3 times to take the mean value.

The bulk density pₛ of the ceramic matrix is calculated according to the formula κ=m₁ρ_{w}/(m₃-m₂), where: mₗ is the weight of the sample after drying (g); m₂ is the floating weight of the sample in water after sufficient water absorption (g); m₃ is the weight of the sample in air after sufficient water absorption (g); and ρ_{w} is the density of water, taken as 1.0g/cm³.

The theoretical density ρₜₕ of the ceramic matrix is calculated according to the formula ρₜₕ=1/(wᵢ/ρᵢ), where: wᵢ is the weight percent of the ith component; and ρᵢ is the theoretical density (g/cm³) of the ith component.

The efficiency of space filling, i. e. the relative density ρᵣ, of the ceramic matrix, is calculated according to the formula ρᵣ=ρₛ/ρₜₕ.

(2) Bending strength of the ceramic matrix was determined by the three-point bending method:

1) the prepared ceramic sample was ground to about 4 mm on both sides of a surface grinder;

2) the sample was processed into 3×4×36 mm cuboid splines using an internal cutting machine and chamfered with a diamond abrasive paste;

3) the test was performed by a YRWT-D microcomputer controlled electronic universal testing machine. The test conditions: a span of 20 mm, a loading speed of 0.5 mm/min, and vertical compression. The bending strength σ_{f} of the ceramic is calculated according to the formula σ_{f}=3FL/2bd², where: σ_{f} is the calculated ceramic flexural strength (MPa); b is the width of the test spline (mm); L is the set test machine span (mm); d is the height of the test spline (mm); F is the loading force (N) shown by the testing machine when the ceramic sample breaks.

For the same ceramic sample, 3 splines were taken for the test, and the mean value after test was taken as the bending strength.

(3) Fracture toughness of the ceramic matrix was tested by the three-point bending method:

1) the sintered ceramic sample was ground to about 4 mm on two sides of a surface grinding machine, and precisely polished with the diamond abrasive paste;

2) the sample was processed into 3×4×40mm cuboid splines using an internal cutting machine and chamfered with the diamond abrasive paste;

3) a notch with a width of about 0.22 mm and a depth of 1.4-1.6 mm was made on the spline parallel to the loading direction by using the diamond internal circle cutting machine;

4) the test was performed by a YRWT-D microcomputer controlled electronic universal testing machine. The span is 20 mm and the loading speed is 0.05 mm/min.

The fracture toughness of the sample is calculated by the following formula.

$${K}_{IC} = \frac{3 P L}{2 b {w}^{2}} [ 1.964 - 2.837 ( \frac{a}{w} ) + 13.711 {( \frac{a}{w} )}^{2} - 23.25 {( \frac{a}{w} )}^{3} + 24.129 {( \frac{a}{w} )}^{4} ]$$

Wherein: K_{IC} is the fracture toughness (MPa.m^{1/2}) of the ceramic sample; a is the spline notch depth (mm); b is the width of the spline (mm); w is the height of the spline (mm); P is the load (N) applied when the spline breaks; and L is the set testing machine span (mm).

For the same sample, 3 splines were taken for the test, and the mean value after test was taken as the fracture toughness value.

The efficiency of space filling, bending strength and fracture toughness of the ceramic matrix obtained in the above-mentioned Examples 1-4 are compared with the high-aluminum ceramic in the invention patent CN109336564 B, and the comparative test results are shown in table 2.

TABLE 2
Comparative test results of ceramic matrixes properties

| | Exam- | Exam- | Exam- | Exam- | |
|---|---|---|---|---|---|
| | ple 1 | ple 2 | ple 3 | ple 4 | Comparative |
| efficiency of space | 95.9 | 98.6 | 97.3 | 96.2 | 88.2 |
| filling (%) | | | | | |
| Flexural Strength | 336 | 357 | 368 | 349 | 172 |
| (MPa) | | | | | |
| Fracture toughness | 3.0 | 3.3 | 3.5 | 3.1 | 1.5 |
| (MPa · m^{1/2}) | | | | | |

According to the comparative test results of the above Examples 1-8, it can be seen that the tensile strength of the sealing component is high, namely, there is a good sealing effect between the ceramic matrix and the metallized layer; the wettability of the ceramic matrix is good; the ceramic matrix has high efficiency of space filling, high bending strength and high fracture toughness, i. e. the ceramic matrix has good efficiency of space filling and mechanical properties, which is suitable as the matrix material of the Al₂O₃-based ceramic welding sealing component.

Each technical feature of the above-mentioned examples can be combined in any combination, and in order to make the description concise, not all the possible combinations of each technical feature in the above-mentioned examples are described. However, as long as there is no contradiction between the combinations of these technical features, they should be considered as the scope of the description.

The examples described above represent only a few examples of the present invention and are described in more detail and should not be construed as limiting the scope of the present invention. It should be noted that several variations and modifications can be made by one skilled in the art without departing from the inventive concept, which is within the scope of the present invention.

We claim:

1. An Al₂O₃-based ceramic welding sealing component comprising a ceramic matrix and a metallized layer, wherein the ceramic matrix is prepared from the following raw materials in parts by weight: 80-90 parts of inorganic fiber-aluminum oxide 3D network matrix, 2-5 parts of yttrium oxide, 1-3 parts of silicon oxide, 2-4 parts of titanium oxide, 0.5-1.0 parts of additive, 3-5 parts of binder and 1-3 parts of dispersant, and the additive, binder and dispersant are LiYO₂, polyvinyl butyral and sodium tripolyphosphate respectively;
a preparation method of the ceramic matrix comprising the steps of:
A1, preparation of inorganic fiber-hexagonal aluminum oxide 3D network matrix:
impregnating the inorganic fibers in a 2 mol/L NaOH solution and a silicone insulating impregnating agent, impregnating for 3-4 h at 70-90° C., filtering and drying to obtain surface-modified inorganic fibers, wherein the mass ratio of the NaOH solution and the silicone insulating impregnating agent is 1:1-2;
mixing the aluminum oxide and the surface-modified inorganic fibers, and reacting under an inert atmosphere at a pressure of 5-10 MPa and a temperature of 80-120° C. for 2-6 h to prepare the inorganic fiber-hexagonal aluminum oxide 3D network matrix, wherein the mass ratio of the surface-modified inorganic fibers to aluminum oxide is 1:4-8;
A2, mixing: mixing silicon oxide, yttrium oxide and the additive uniformly, adding same to the inorganic fiber-aluminum oxide 3D network matrix prepared in step A1, then adding titanium oxide, the dispersant and water, and performing high-speed ball-milling for 6-8 h;
A3, granulation: performing suction filter on the milled slurry, and then processing same into a granular ceramic powder with an average particle size of 20-40 μm by a centrifugal spray drier for later use;
A4, primary sintering: loading the ceramic powder obtained in step A3 into a hot-pressing mold, and performing normal temperature sintering at 1000-1200° C. with nitrogen as a protective gas, with the temperature-holding time being 1-2 h to prepare a ceramic blank; and
A5, secondary sintering: loading the ceramic blank obtained in step A4 into a hot-pressing mold, using nitrogen as a protective gas, sintering at 1600-1800° C. under normal pressure, with the temperature-holding time being 2-3 h; after cooling to room temperature in a furnace, taking out the sintered product, and then polishing same on a surface grinding machine to prepare a ceramic matrix to be metallized.

2. The Al₂O₃-based ceramic welding sealing component of claim 1, wherein the inorganic fiber of step Al is one of silicon carbide fiber, aluminum nitride fiber or silicon oxide fiber.

3. The Al₂O₃-based ceramic welding sealing component of claim 1, wherein during the ball-milling of step A2, the ball-milling rate is 360 r/min and the ball-to-material ratio is 10:1.

4. (canceled)

5. (canceled)
